(19) United States
(12) Patent Application Publication
(10) Pub. No.: US 2026/0264315 A1
(43) Pub. Date: Sep. 10, 2026

(54) DETERMINATION METHOD, SHAPING METHOD, ARTICLE MANUFACTURING METHOD, INFORMATION PROCESSING APPARATUS, STORAGE MEDIUM, AND SHAPING APPARATUS

(71) Applicant: CANON KABUSHIKI KAISHA, Tokyo (JP)

(72) Inventor: RYOHEI SUZUKI, Tochigi (JP)

(21) Appl. No.: 19/557,708

(22) Filed: Mar. 5, 2026

(30) Foreign Application Priority Data
Mar. 10, 2025 (JP) 2025-037707

(51) Int. Cl. B29C 59/02; B29C 33/42; B29C 37/00; B29C 59/00

(52) U.S. Cl. CPC B29C 59/02; B29C 33/424; B29C 59/002; B29C 2037/903

(57) ABSTRACT

A determination method of determining a control profile used to control a mechanism operated in a shaping process of shaping a composition is provided. The method includes acquiring a processing condition used for the shaping process, obtaining an evaluation value concerning a state of the composition in a case where the shaping process is performed under the processing condition, adjusting an element constituting a function representing the control profile so that the evaluation value falls within a predetermined range, and determining the control profile based on the adjusted element, wherein the obtaining the evaluation value includes obtaining, for each of a plurality of sub-regions, a sub-evaluation value concerning a state of the composition, and obtaining the evaluation value based on sub-evaluation values obtained for the plurality of sub-regions.

### BACKGROUND

### Field of the Technology

The present disclosure relates to a determination method, a shaping method, an article manufacturing method, an information processing apparatus, a storage medium, and a shaping apparatus.

### Description of the Related Art

There is known a shaping technique (shaping process) of shaping a composition on a substrate by bringing the composition arranged on the substrate and a mold into contact with each other. Such a shaping technique is applicable to an imprint apparatus and a planarization apparatus. The imprint apparatus uses a mold having a contact surface including a concave-convex pattern, and the pattern of the mold is transferred to a composition on a substrate by curing the composition in a state in which the composition on the substrate and the contact surface are in contact with each other. The planarization apparatus uses a mold having a flat contact surface, and a film of a composition having a flat surface is formed on a substrate by curing the composition in a state in which the composition on the substrate and the contact surface are in contact with each other.

In the shaping technique, for example, in an operation of bringing the mold and the composition on the substrate into contact with each other, a pressing force for pressing the mold against the composition on the substrate, a pressure (a so-called cavity pressure) for bulging the contact surface of the mold toward the substrate, and the like are temporally controlled in accordance with a predetermined control profile. Japanese Patent No. 5433584 describes that in an imprint process, the pressing force and the cavity pressure are controlled based on the height profile between a mold (template) and a substrate.

In a shaping process, composition shaping failure such as bubble defects can occur. When the shaping condition is optimized using a method such as Bayesian optimization that does not involve human intervention to reduce the shaping failure across the entire pattern region, the shaping failure tends to be unevenly distributed.

In particular, as for an imprint apparatus, it is known that bubble defects are likely to occur in the corner portion and complex pattern portion of a mold. Determining control parameters to improve such regions is one of the key factors in ensuring apparatus performance.

### SUMMARY

The present disclosure provides a technique advantageous for suppressing shaping failure.

The present disclosure in one aspect provides a determination method of determining a control profile used to control a mechanism operated in a shaping process of shaping a composition on a substrate using a mold, the method including acquiring a processing condition used for the shaping process, obtaining an evaluation value concerning a state of the composition in a case where the shaping process is performed under the processing condition, adjusting an element constituting a function representing the control profile so that the evaluation value falls within a predetermined range, and determining the control profile based on the adjusted element, wherein the obtaining the evaluation value includes obtaining, for each of a plurality of sub-regions obtained by dividing a region where the shaping process is performed, a sub-evaluation value concerning a state of the composition in a case where the shaping process is performed under the processing condition, and obtaining the evaluation value based on a plurality of sub-evaluation values obtained for the plurality of sub-regions.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIGS. 1A and 1B are views exemplarily showing the arrangement and operation of an imprint apparatus;

FIG. 2 is a view exemplarily showing the configuration of an imprint system;

FIG. 3 is a view exemplarily showing the hardware arrangement of a server apparatus;

FIG. 4 is a flowchart of a determination method;

FIGS. 5A to 5C are views each exemplarily showing defects output from a simulator;

FIG. 6 is a flowchart of an evaluation value calculation method;

FIG. 7 is a graph exemplarily showing the transition of the bubble defect count with respect to the imprint elapsed time;

FIGS. 8A to 8D are graphs each exemplarily showing a control profile in a control mechanism related to a contact operation;

FIG. 9 is a view exemplarily showing a graph of a control parameter having a constant value;

FIG. 10 is a view exemplarily showing a graph of a control parameter that changes proportionally to time;

FIG. 11 is a view exemplarily showing a graph of a control parameter that changes nonlinearly with respect to time;

FIG. 12 is a view exemplarily showing a graph of a control parameter that changes in an S-shape with respect to time;

FIG. 13 is a view exemplarily showing a graph of a control parameter represented by different curves for each time section;

FIG. 14 is a view exemplarily showing a graph of a control parameter that changes according to a spline curve;

FIG. 15 is a graph exemplarily showing the dominance relationship among solutions in multi-objective optimization;

FIGS. 16A and 16B are views exemplarily showing a result evaluation method in an MOTPE method;

FIG. 17 is a flowchart of an evaluation value calculation method; and

FIG. 18 is a view for explaining an article manufacturing method in an embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

A shaping apparatus according to the present disclosure is an apparatus that performs a shaping process of shaping a composition on a substrate using a mold. Examples of the shaping apparatus are an imprint apparatus and a planarization apparatus. The imprint apparatus is an apparatus that brings a mold including a concave-convex pattern into contact with a composition (imprint material) on a substrate to form (transfer) the pattern in the composition. The shaping process performed by the imprint apparatus is sometimes called an imprint process. The planarization apparatus is an apparatus that planarizes the surface of a composition by bringing a mold having a flat surface into contact with the composition on a substrate. In the mold used in the planarization apparatus, 90% or more (preferably 95% or more) of the contact surface that comes into contact with the composition on the substrate can be formed as a flat surface in which no concave-convex pattern is formed. The shaping process performed by the planarization apparatus is sometimes called a planarization process. In the following description, the imprint apparatus will be exemplified as the shaping apparatus, but arrangements/processes of the imprint apparatus can also be applied to the planarization apparatus.

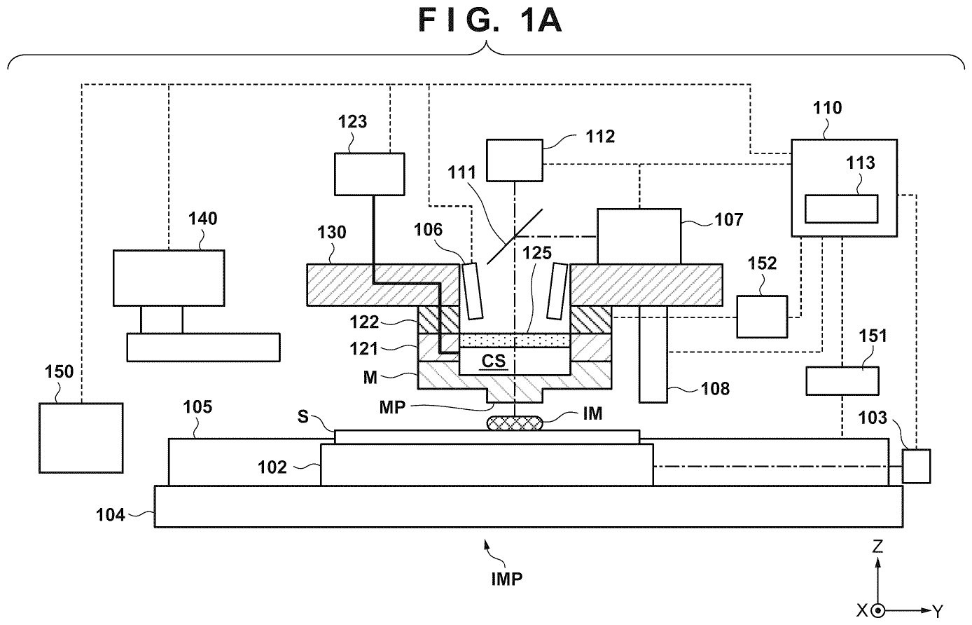

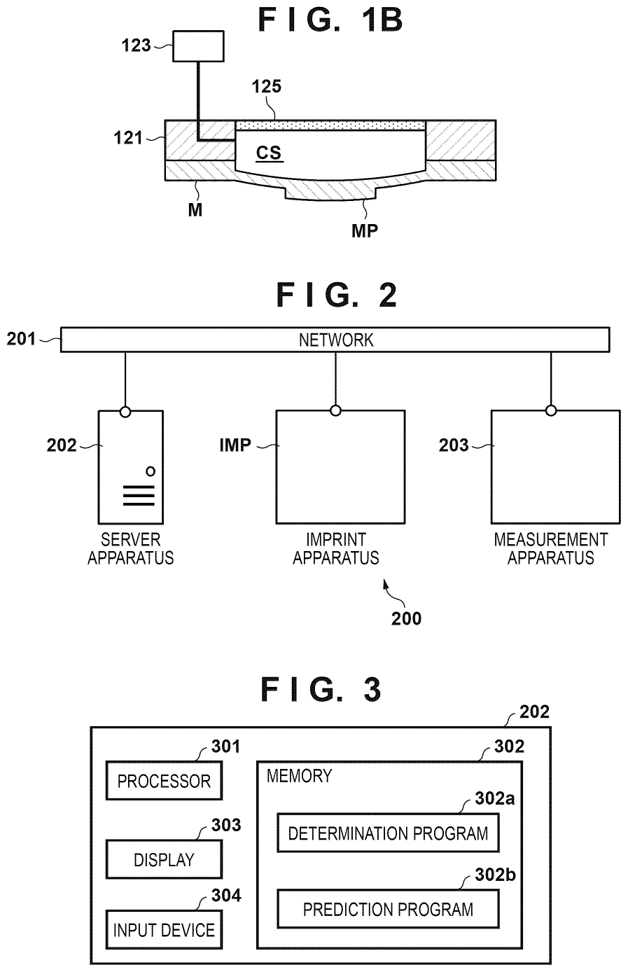

An imprint apparatus IMP according to an embodiment will be described. FIG. 1A is a schematic view showing an example of the arrangement of the imprint apparatus IMP according to this embodiment. The imprint apparatus IMP is an apparatus that brings a mold and an imprint material (composition) supplied onto a substrate into contact with each other, and applies curing energy to the imprint material, thereby forming a pattern of a cured product to which the concave-convex pattern of the mold has been transferred. For example, the imprint apparatus IMP supplies a liquid imprint material IM as a plurality of droplets onto a substrate S, and cures the imprint material in a state in which a mold M (mold) formed with a concave-convex pattern is in contact with the imprint material IM on the substrate S. Then, the imprint apparatus IMP increases the spacing between the mold M and the substrate S to separate the mold M from the cured imprint material IM. Thus, the pattern of the mold M can be transferred to the imprint material IM on the substrate S. Such a series of processes is called an “imprint process”, and is performed for each of a plurality of shot regions of the substrate S.

As the imprint material IM, a curable composition (to be also referred to as a resin in an uncured state) to be cured by receiving curing energy is used. As the curing energy, an electromagnetic wave, heat, or the like can be used. The electromagnetic wave can be, for example, light selected from the wavelength range of 10 nm (inclusive) to 1 mm (inclusive), for example, infrared light, visible light, or ultraviolet light. The curable composition can be a composition cured by light irradiation or heating. Among these, the photo-curable composition cured by light irradiation contains at least a polymerizable compound and a photopolymerization initiator, and may further contain a nonpolymerizable compound or a solvent, as needed. The nonpolymerizable compound is at least one type of material selected from a group consisting of a sensitizer, a hydrogen donor, an internal mold release agent, a surfactant, an antioxidant, a polymer component, and the like. The imprint material IM can be arranged on the substrate S in a droplet shape or in an island or film shape formed by connecting a plurality of droplets. The viscosity (the viscosity at 25° C.) of the imprint material IM can be, for example, 1 mPa·s (inclusive) to 100 mPa·s (inclusive). As the material of the substrate S, for example, glass, a ceramic, a metal, a semiconductor, a resin, or the like can be used. A member made of a material different from that of the substrate S may be provided on the surface of the substrate S, as needed. The substrate S is, for example, a silicon wafer, a compound semiconductor wafer, or silica glass.

In the specification and the accompanying drawings, directions will be indicated on an XYZ coordinate system in which directions parallel to the surface of the substrate S are defined as an X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, OY, and OZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the OX-axis, the OY-axis, and the OZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Positioning means controlling the position and/or the posture. Alignment can include control of the position and/or the posture of at least one of the substrate and the mold.

The imprint apparatus IMP can include a substrate holding unit 102 that holds the substrate S, a substrate driving mechanism 105 that drives the substrate S by driving the substrate holding unit 102, a base 104 that supports the substrate holding unit 102, and a position measurement unit 103 that measures the position of the substrate holding unit 102. The substrate driving mechanism 105 can include, for example, a motor such as a linear motor. The imprint apparatus IMP can include a sensor 151 that detects the substrate driving force (alignment load) required for the substrate driving mechanism 105 to drive the substrate S (substrate holding unit 102) during alignment between the mold M and the substrate S. The substrate driving force in an alignment operation, which is performed in a state in which the imprint material IM on the substrate S and a pattern region MP of the mold M are in contact with each other, corresponds to, for example, a shear force that acts between the substrate S and the mold M. The shear force is a force that acts mainly in the plane direction (X and Y directions) of the substrate S and the mold M. The substrate driving force during alignment is, for example, correlated to the magnitude of a current supplied to the motor of the substrate driving mechanism 105 during alignment. The sensor 151 can detect the substrate driving force based on the magnitude of the current. The sensor 151 is an example of the sensor for measuring the influence (shear force) received by the mold M during the pattern formation.

The imprint apparatus IMP can include a mold holding unit 121 that holds the mold M (mold), a mold driving mechanism 122 that drives the mold M by driving the mold holding unit 121, and a support structure 130 that supports the mold driving mechanism 122. The mold driving mechanism 122 can include, for example, a motor such as a voice coil motor. The imprint apparatus IMP can include a sensor 152 that detects a pressing force and/or a mold separation force (separation load). The pressing force is a force of pressing the mold M against the imprint material IM on the substrate S to bring the mold M and the imprint material IM on the substrate S into contact with each other. The mold separation force is a force required to separate the cured product of the imprint material IM on the substrate S and the mold M from each other. The pressing force and the mold separation force are forces that act mainly in a direction (Z direction) perpendicular to the plane direction of the substrate S and the mold M. Each of the pressing force and the mold separation force is, for example, correlated to the magnitude of the current supplied to the motor of the mold driving mechanism 122. The sensor 152 can detect the pressing force and the mold separation force based on the magnitude of the current. The sensor 152 is an example of the sensor for measuring the influence (the pressing force and/or the mold separation force) received by the mold M during the pattern formation.

The substrate driving mechanism 105 and the mold driving mechanism 122 form a driving mechanism that adjusts the relative position and relative posture between the substrate S and the mold M. Adjustment of the relative position between the substrate S and the mold M by the driving mechanism includes driving for bringing the mold M into contact with the imprint material IM on the substrate S and driving for separating the mold M from the cured imprint material IM (the pattern of a cured product). The substrate driving mechanism 105 can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis). The mold driving mechanism 122 can be configured to drive the mold M with respect to a plurality of axes (for example, three axes including the Z-axis, θX-axis, and θY-axis, and preferably six axes including the X-axis, Y-axis, Z-axis, θX-axis, θY-axis, and θZ-axis).

The mold holding unit 121 can include a window member 125 for forming a pressure control space CS on the side of the back surface (the surface on the opposite side of the pattern region MP where the pattern to be transferred to the substrate S is formed) of the mold M. The imprint apparatus IMP can include a deformation mechanism 123 that deforms the pattern region MP of the mold M into a convex shape toward the substrate S as schematically shown in FIG. 1B by controlling the pressure (to be sometimes referred to as the “cavity pressure” hereinafter) in the pressure control space CS. For example, when the mold M is deformed into a convex shape in a contact operation of bringing the mold M into contact with the imprint material IM on the substrate S, the mold M (pattern region MP) can gradually be brought into contact with the imprint material IM on the substrate S, thereby reducing confinement of a gas in the concave portions of the pattern of the mold M. That is, non-filling of the imprint material IM into the pattern of the mold M can be reduced. Also, when the mold Mis deformed into a convex shape in a mold separation operation of separating the mold M from the cured product of the imprint material IM on the substrate S, breakage of the pattern made of the cured product of the imprint material IM formed on the substrate S can be reduced. Note that the cavity pressure may be understood as a force (deformation force) applied to the mold M to deform the mold M into a convex shape.

The imprint apparatus IMP can include a mold conveyance mechanism 140 that conveys the mold M, and a mold cleaner 150. The mold conveyance mechanism 140 can be configured to, for example, convey the mold M to the mold holding unit 121 and convey the mold M from the mold holding unit 121 to an original stocker (not shown), the mold cleaner 150, or the like. The mold cleaner 150 cleans the mold M using ultraviolet light, a chemical solution, or the like.

The imprint apparatus IMP can include an alignment measurement device 106. The alignment measurement device 106 illuminates an alignment mark on the substrate S and an alignment mark on the mold M and captures images of these alignment marks, thereby measuring the relative position between the marks. The imprint apparatus IMP is provided with a plurality of alignment measurement devices 106, and can simultaneously observe a plurality of alignment marks formed in the shot region of the substrate S and the mold M by the plurality of alignment measurement devices 106. For example, the imprint apparatus IMP can be provided with four alignment measurement devices 106 for observing alignment marks formed at four corners of each of the shot region of the substrate S and the mold M. The alignment measurement device 106 can be positioned by a driving mechanism (not shown) in accordance with the positions of alignment marks to be observed. An image captured by the alignment measurement device 106 will be referred to as an alignment image hereinafter, and an alignment mark position measured by the alignment measurement device 106 will be referred to as an alignment measurement value hereinafter. An example of the alignment image obtained by the alignment measurement device 106 is an image obtained by capturing (detecting) reflected light from each alignment mark of the substrate S and the mold M. Alternatively, the alignment image may be an image obtained by capturing (detecting) an image formed by moiré of each alignment mark of the substrate S and the mold M.

The imprint apparatus IMP can include a curing unit 107, an image capturing unit 112, and an optical member 111 (beam splitter). The curing unit 107 irradiates the imprint material IM on the substrate S with energy (for example, light such as ultraviolet light) for curing the imprint material IM via the optical member 111, thereby curing the imprint material IM. The image capturing unit 112 captures images of the substrate S, the mold M, and the imprint material IM on the substrate S via the optical member 111 and the window member 125. Note that an image captured by the image capturing unit 112 may be referred to as a spread image.

The imprint apparatus IMP can include a dispenser 108 that arranges (supplies) the imprint material IM as a plurality of droplets on the substrate S. For example, the dispenser 108 discharges the imprint material IM such that the imprint material IM is arranged as a plurality of droplets on the substrate S in accordance with an arrangement pattern indicating the arrangement of the droplets of the imprint material IM.

The imprint apparatus IMP can include a control unit 110 that controls the substrate driving mechanism 105, the mold driving mechanism 122, the deformation mechanism 123, the mold conveyance mechanism 140, the mold cleaner 150, the alignment measurement device 106, the curing unit 107, the image capturing unit 112, the dispenser 108, and the like. The control unit 110 can include, as an arithmetic apparatus 113, for example, an information processing apparatus (computer) including a processor such as a Central Processing Unit (CPU) and a memory. Alternatively, the control unit 110 may include, as the arithmetic apparatus 113, for example, a PLD (the abbreviation of Programmable Logic Device) such as an FPGA (the abbreviation of Field Programmable Gate Array), an ASIC (the abbreviation of Application Specific Integrated Circuit), a general-purpose computer incorporating a program, or a combination of some or all of these.

This embodiment has as its object to determine a control profile used to temporally control a mechanism (to be sometimes referred to as an operation mechanism hereinafter) operated in an imprint process (shaping process) of the imprint apparatus IMP. The imprint process includes a contact operation (pressing operation) of bringing the mold M into contact with the imprint material IM on the substrate S, and a mold separation operation of separating the mold M from the cured product of the imprint material IM on the substrate S, and can be performed by operating a plurality of kinds of operation mechanisms. The plurality of kinds of operation mechanisms can include, for example, the substrate driving mechanism 105 that drives the substrate S, the mold driving mechanism 122 that drives the mold M, and the deformation mechanism 123 that controls the pressure (cavity pressure) in the pressure control space CS.

The control profile is a profile indicating the temporal driving target value of each operation mechanism in the imprint process, and the driving target value can change as time elapses. The control profile can influence the state of the imprint material IM (for example, defects generated in the film of the imprint material IM, the shape (thickness) of the film, and the like) on the substrate S shaped by the imprint process. It is difficult to detect such a state of the imprint material IM based only on information obtained from the sensor in the imprint apparatus IMP. In addition, since the state of the imprint material IM (for example, the tendency for the defect to occur) can change in accordance with the processing condition used for the imprint process, it is necessary to determine the control profile every time the processing condition is changed. Hence, a technique for appropriately and easily determining the control profile is desired. This embodiment provides a method of more efficiently adjusting one or more elements that define a function representing the control profile and using the elapsed time of the imprint process as a variable. Note that the one or more elements can include at least one of a coefficient and a constant that define the function representing the control profile, and may be referred to as “one or more parameter values” below.

FIG. 2 shows an example of the configuration of a system 200 for determining a control profile. The system 200 can include the imprint apparatus IMP, a server apparatus 202, and a measurement apparatus 203. These apparatuses can transmit and receive information and data via a network 201. For example, information and data required by the server apparatus 202 can be provided to the server apparatus 202 via the network 201.

The server apparatus 202 is an apparatus (optimization server) for determining a control profile used to temporally control each operation mechanism of the imprint apparatus IMP, and can include a program for determining the control profile by adjusting one or more parameter values. The server apparatus 202 can be formed from, for example, an information processing apparatus (computer) including a processor such as a Central Processing Unit (CPU) and a memory. The control profile determined by the server apparatus 202 can be provided to the imprint apparatus IMP via the network 201. Here, in this embodiment, an example in which the control profile is determined by the server apparatus 202 will be described. However, the control profile is not limited to this, and may be determined by the control unit 110 (arithmetic apparatus 113) of the imprint apparatus IMP.

The measurement apparatus 203 is an apparatus that measures (inspects) the state of the imprint material IM shaped on the substrate S by the imprint apparatus IMP. For example, the measurement apparatus 203 can measure, as the state of the imprint material IM, the positions and number of defects generated in the imprint material IM, the thickness of the imprint material IM, or the like. The measurement result of the measurement apparatus 203 can be provided to the server apparatus 202 via the network 201. Here, if the state of the imprint material IM is obtained (predicted) by simulation, the measurement apparatus 203 may not be provided in the system 200. The simulation can be executed by the server apparatus 202.

FIG. 3 shows an example of the hardware arrangement of the server apparatus 202 that determines the control profile. In the example shown in FIG. 3, the server apparatus 202 can include a processor 301, a memory 302, a display 303, and an input device 304. The processor 301 performs information processing for determining the control profile, and information processing for predicting (simulating) the state of the imprint material IM shaped on the substrate S by the imprint process. The memory 302 is a data read/write memory, and can be used to save programs and data. A determination program 302a for determining the control profile and a prediction program 302b for predicting (simulating) the state of the imprint material IM to be obtained by the imprint process are stored in the memory 302. The programs 302a and 302b are executed by the processor 301. The display 303 is an apparatus for displaying information required for the operation of the server apparatus 202, the result of information processing performed by the processor 301, and the like. An example of the display 303 is a Cathode Ray Tube (CRT), a liquid crystal monitor, or the like. The input device 304 is a device for the user to input characters and data to the server apparatus 202. Examples of the input device 304 include various kinds of keyboards and a mouse.

### Example 1

In Example 1, a determination method of the control profile for each operation mechanism operated in the imprint process of the imprint apparatus IMP will be described. The object here is to obtain an imprint condition that ensures even distribution of residual bubbles across the entire pattern region without the residual bubbles being unevenly distributed in regions prone to residual bubbles.

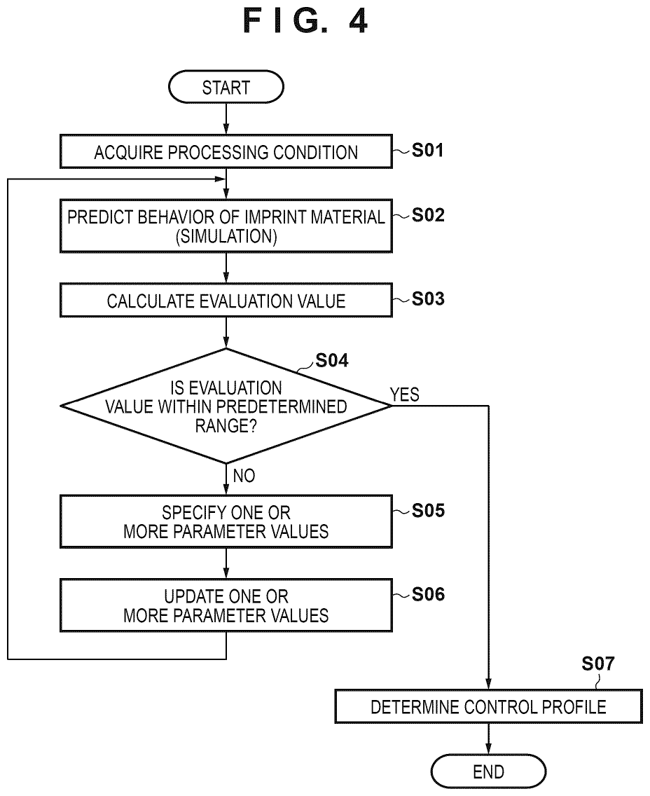

FIG. 4 is a flowchart illustrating the determination method of the control profile for each operation mechanism. If a plurality of kinds of operation mechanisms are operated in the imprint process of the imprint apparatus IMP, the flowchart of FIG. 4 is executed for each of the plurality of kinds of operation mechanisms. That is, the control profile is individually determined for each of the plurality of kinds of operation mechanisms.

Here, in Example 1, an example will be described in which the flowchart of FIG. 4 is executed by the processor 301 of the server apparatus 202 in accordance with the determination program 302a. However, the flowchart of FIG. 4 may be executed by the control unit 110 (arithmetic apparatus 113) of the imprint apparatus IMP. In addition, an example will be described in which the state of the imprint material IM to be obtained by the imprint process is predicted (simulated) by the processor 301 of the server apparatus 202 in accordance with the prediction program 302b, but the state may be measured using the measurement apparatus 203.

In step S01, the processor 301 acquires the processing condition used for the imprint process of the imprint apparatus IMP. The processing condition can include at least one of, for example, the density of the concave-convex pattern provided in the pattern region MP of the mold M, the depth of the concave portion (groove) of the concave-convex pattern, the target film thickness of the imprint material IM, and the arrangement of the imprint material IM supplied as a plurality of droplets onto the substrate S. The target film thickness of the imprint material IM may be understood as the thickness of the imprint material IM to be formed on the substrate S through the imprint process, that is, the thickness of the imprint material IM after formation (shaping) by the imprint process. The processor 301 may acquire the processing condition based on the information input by the user via the input device 304, or may acquire the processing condition based on the design data of the mold M, the target shape data of the imprint material, or the like.

In this embodiment, one or more parameter values are adjusted such that the evaluation value concerning the state of the imprint material IM in a case where the imprint process is performed under the processing condition acquired in step S01 falls within a predetermined range. Here, the type of the function representing the control profile is different among the plurality of kinds of operation mechanisms. One or more parameter values can be adjusted for each kind of the operation mechanism.

In step S02, the processor 301 executes, in accordance with the prediction program 302b, a simulation of predicting the behavior of the imprint material IM on the substrate S in a case where the imprint process is performed under the processing condition acquired in step S01. More specifically, the processor 301 simulates the imprint apparatus IMP, the mold M, the substrate S, the imprint material IM, and the environment in the apparatus, and sequentially operates each operation mechanism in the imprint apparatus IMP in accordance with the control profile. With this, as the result of the simulation, the state of the imprint material IM (for example, defects generated in the film of the imprint material IM, the shape and thickness of the film, or the like) corresponding to the elapsed time from the start of the imprint process can be predicted. Here, in step S02 for the first time, the simulation can be performed using the control profile (initial setting) set in advance for each operation mechanism. On the other hand, in step S02 for the second and subsequent times, the simulation can be performed using the control profile with one or more parameter values updated (changed) in step S06 (to be described later).

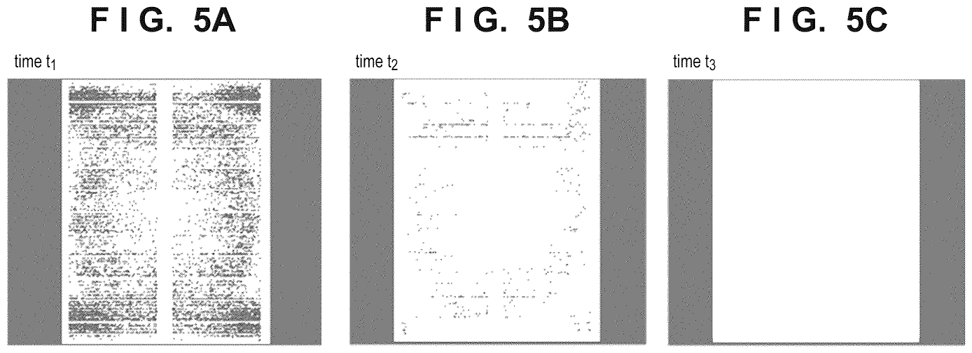

Each of FIGS. 5A to 5C shows, as the result of the simulation in step S02, the defect distribution generated in the imprint material IM on the substrate S by the imprint process. Here, as the kind of the defect, a bubble defect generated when filling of the imprint material IM into the concave portion of the concave-convex pattern of the mold M is insufficient (for example, non-filling) is exemplified. FIGS. 5A to 5C show the temporal simulation results of the defect distribution generated in the imprint material IM in the contact operation of the imprint process. FIG. 5A shows the defect distribution at time t₁ in the early stage of the contact operation, FIG. 5B shows the defect distribution at time t₂ after time t₁, and FIG. 5C shows the defect distribution at time t₃ at the end of the contact operation. As shown in FIGS. 5A to 5C, at time t₁ in the early stage of the contact operation, there are bubble defects in the whole area of the shot region of the substrate S. At time t₂ when the contact operation has further progressed, the bubble defects have decreased. At time t₃ at the end of the contact operation, the bubble defects have further decreased, and there is almost no bubble defect.

Here, in step S02, in addition to or instead of the defects of the imprint material IM, the processor 301 can predict, as the state of the imprint material IM, the shape (thickness) of the imprint material IM or the position deviation of the pattern transferred to the imprint material IM. That is, as the state of the imprint material IM, the processor 301 can predict at least one of the defect of the imprint material IM, the shape of the imprint material IM, and the position deviation of the pattern of the imprint material IM, which are generated by the imprint process. The position deviation of the pattern of the imprint material IM may be understood as the position deviation between the mold M and the substrate S, that is, the difference between the target position on the substrate S where the pattern of the mold M should be transferred and the position on the substrate S where the pattern of the mold M is actually transferred.

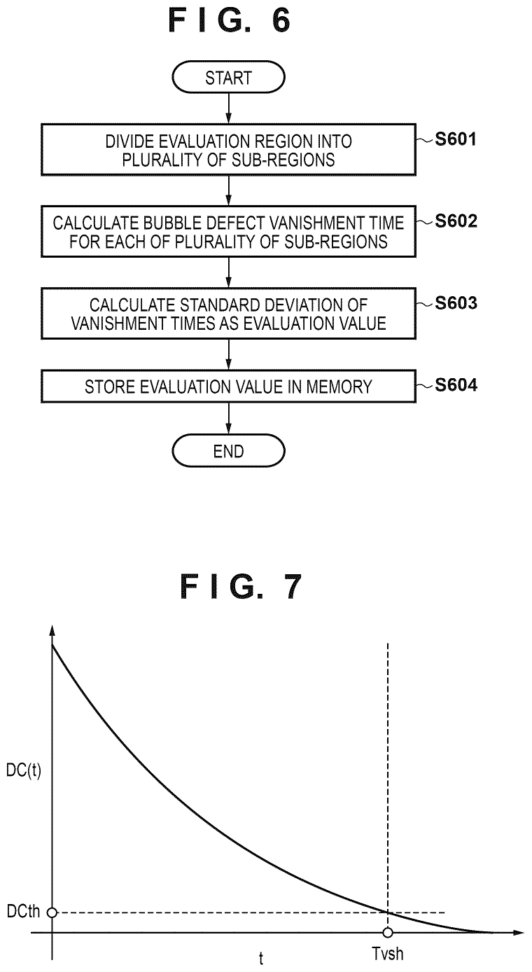

Step S03 is an evaluation step of obtaining an evaluation value concerning the state of the composition in a case where the shaping process is performed under the processing condition acquired in step S01. In step S03, the processor 301 calculates an evaluation value from the simulation result obtained in step S02. FIG. 6 shows the detailed procedure of a calculation method of the evaluation value concerning bubble defects in step S03.

In step S601, the processor 301 divides the imprint evaluation region into a plurality of sub-regions. The sizes of the plurality of sub-regions may be different from each other. If the region prone to bubble defects is known in advance, it is desirable to determine the division range such that the plurality of sub-regions include the region.

Step S602 is a step (first step) of obtaining, for each of the plurality of sub-regions obtained by dividing the region where the shaping process is performed, a sub-evaluation value concerning the state of the composition in a case where the shaping process is performed under the acquired processing condition. In step S602, the processor 301 obtains the bubble defect vanishment time (sub-evaluation value) for each of the plurality of sub-regions obtained in step S601. FIG. 7 shows a graph exemplarily showing the transition of the bubble defect count with respect to the imprint elapsed time. An ordinate DC (t) represents the bubble defect count (total count), and an abscissa t represents the time from the start of the imprint process. DCth represents the threshold value for the bubble defect count. As shown in FIG. 7, the bubble defect count decreases as the time elapses, and the time at which the bubble defect count first falls below DCth is defined as a bubble defect vanishment time Tvsh. The processor 301 obtains the bubble defect vanishment time Tvsh for each of the divided regions.

Step S603 is a step (second step) of obtaining an evaluation value based on a plurality of sub-evaluation values obtained for the plurality of sub-regions. For example, in step S603, the processor 301 calculates the standard deviation and minimum value of the bubble defect vanishment times respectively obtained for the plurality of sub-regions. By obtaining the standard deviation, it is possible to evaluate the variation in the bubble defect vanishment times of respective sub-regions. When the standard deviation is smaller, the condition can be evaluated as resulting in less localized generation of bubble defects. The minimum value of the obtained bubble defect vanishment times may also be added as an evaluation value. Adding the minimum value of the bubble defect vanishment times as an evaluation value prevents the condition under which the bubble defect vanishment times are uniformly slow in all regions from being considered optimal. Although the standard deviation is obtained here, it need not be the standard deviation as long as it is an index that indicates the variation in the evaluation values respectively obtained for the sub-regions. For example, a variance or a coefficient of variation may be obtained instead of the standard deviation. Instead of the minimum value, an average value or the like may be obtained as long as the length of bubble defect vanishment time is evaluated.

In step S604, the processor 301 stores the evaluation value obtained in step S603 in the memory 302.

The above is the evaluation value calculation method executed in step S03. Here, it has been exemplarily described that the composition defects (bubble defects) are used to obtain the evaluation value (sub-evaluation value). However, in the evaluation step, instead of or in addition to the defects of the composition occurring in the shaping process, the sub-evaluation value may be obtained based on at least one of the shape of the composition and the position deviation of the pattern of the composition.

In this embodiment, the evaluation value (sub-evaluation value) is calculated based on the simulation result obtained in step S02, but the evaluation value is not limited to this. For example, the evaluation value may be calculated based on the actual result of the imprint process performed on a test substrate. In this case, in step S02, instead of the simulation, the imprint process is actually performed on a test substrate. Then, the defect of the imprint material IM, the shape of the imprint material IM, and/or the position deviation of the pattern of the imprint material IM on the test substrate are measured by the measurement apparatus 203. With this, in step S03, the processor 301 can obtain the information indicating the measurement result of the measurement apparatus 203 via the network 201, and calculate the evaluation value based on the measurement result.

In step S04, the processor 301 determines whether the evaluation value calculated in step S03 falls within the predetermined range. For example, if the standard deviation (evaluation value) of the bubble defect vanishment times is smaller than a threshold value and the minimum value of the bubble defect vanishment times is smaller than a threshold value, it is determined that the evaluation value falls within the predetermined range. If the evaluation value falls within the predetermined range, the process advances to step S05; otherwise, the process advances to step S07. As another determination method, if the parameter value update (step S06) count is not larger than a predetermined count, or if the parameter value update (step S06) processing time is not greater than a predetermined time, the process may advance to step S05.

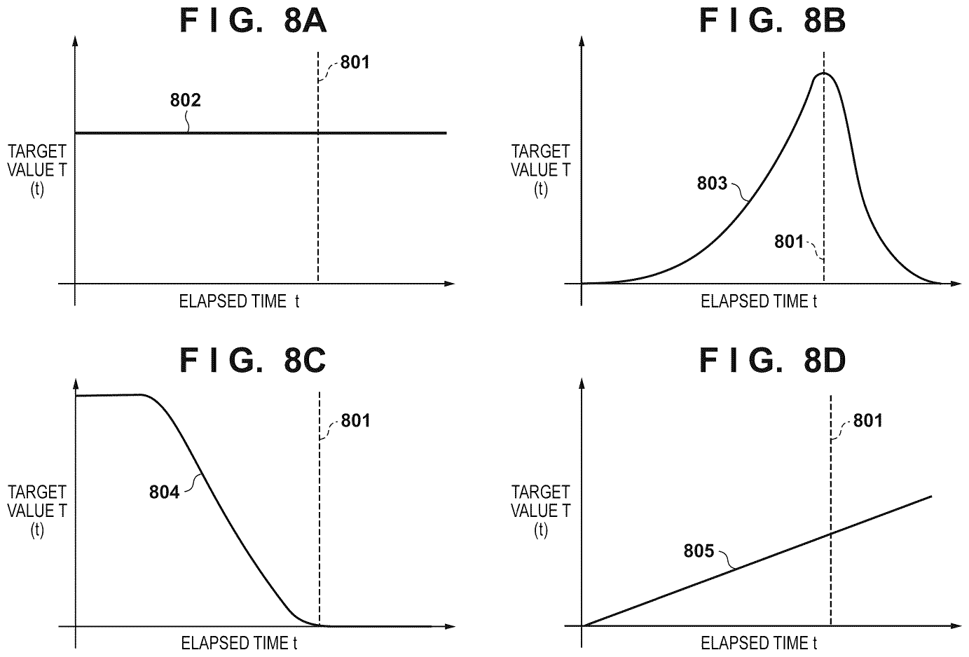

Steps S05 and S06 correspond to an adjustment step of adjusting the element constituting a function representing the control profile so that the evaluation value falls within the predetermined range. In step S05, the processor 301 specifies (extracts) one or more parameter values that define the function representing the control profile. As described above, one or more parameter values are one or more elements that define the function representing the control profile and using the elapsed time of the imprint process as a variable, and can include at least one of a coefficient and a constant that define the function. The processor 301 can specify one or more parameter values for each control profile. For example, the processor 301 can specify one or more parameter values in the control profile in accordance with the kind of the operation mechanism for which the control profile is determined. Each of FIGS. 8A to 8D exemplarily shows the control profile used in the control mechanism related to the contact operation.

FIG. 8A shows a graph shape 802 of the control profile where the target value T(t) has a constant value regardless of the elapsed time t. As an example, the target position of the mold M in the Z direction when the mold M starts to contact the imprint material IM on the substrate S in the contact operation can be controlled using the control profile having the graph shape 802.

FIG. 8B shows a graph shape 803 of the control profile where the target value T(t) increases as the elapsed time t increases in the early stage, the target value T(t) reaches the maximum value around time 801, and the target value T(t) decreases from time 801. This graph shape 803 can be represented by, for example, a spline function or a nonlinear function. As an example, the target value of the pressing force applied to the mold M to press the mold M against the imprint material IM on the substrate S in the contact operation can be controlled using the control profile having the graph shape 803.

FIG. 8C shows a graph shape 804 of the control profile where the target value T(t) is constant in the early stage of the contact operation, the target value T(t) decreases thereafter, and the target value T(t) becomes constant around 0 from time 801. The graph shape 804 can be represented by, for example, an S-shaped function or a sigmoid function. As an example, the target value of the pressure (cavity pressure) applied to the pressure control space CS by the deformation mechanism 123 can be controlled using the control profile having the graph shape 804.

FIG. 8D shows a graph shape 805 of the control profile where the target value T(t) changes linearly as the elapsed time t increases. The graph shape 805 can be represented by, for example, a linear function. As an example, the driving amount of the mold M in the −Z direction from a reference position in the contact operation can be controlled using the control profile having the graph shape 805. In the mold separation operation, in order to gradually separate the mold M from the cured product of the imprint material IM on the substrate S from the center of the substrate S toward the outside, the holding region of the substrate S by the substrate holding unit 102 may be changed from the center of the substrate S toward the outside. In this case, the position of the substrate S (the distance from the centroid of the substrate S) held by the substrate holding unit 102 can be controlled using the control profile having the graph shape 805.

In this manner, the control profiles used in the imprint process are represented by various functions. As described above, examples of the various functions can include the function where the target value T(t) is constant with respect to the elapsed time t, the function where the target value T(t) changes linearly with respect to the elapsed time t, and the function where the target value T(t) changes nonlinearly (with a curve) with respect to the elapsed time t. The characteristics of the control parameters are not limited to the target position, velocity, and force, and may include a plurality of other characteristics such as the change amount per unit time of the target velocity, target acceleration, or the like.

As indicated by the control profiles shown in FIGS. 8A to 8D, each operation (for example, the contact operation or the mold separation operation) in the imprint process is performed in cooperation of a plurality of kinds of operation mechanisms, and the control profile can change along with the elapsed time t (time). Adjustment (determination) of the control profiles used to control various kinds of operation mechanisms as described above is conventionally performed by determining an optimum combination of the control profiles selected from a large number of control profile candidates that differ depending on the elapsed time and the operation mechanism, and this has been a work requiring enormous man-hours. To solve this problem, in this embodiment, one or more parameter values that define the function representing the control profile are specified, and the one or more parameter values are adjusted, thereby shortening the time required for the adjustment work of the control profile. That is, in this embodiment, since one or more parameter values that define the function representing the control profile are simply adjusted, the number of targets to be adjusted can be reduced, and as a result, the time required for adjusting the control profile can be shortened. Note that specifying one or more parameter values that define the function representing the control profile may be understood as approximating the control profile with a smaller finite number of parameter values.

A method of specifying and adjusting one or more parameter values for each type of the graph shape that the control profile can have will be described below.

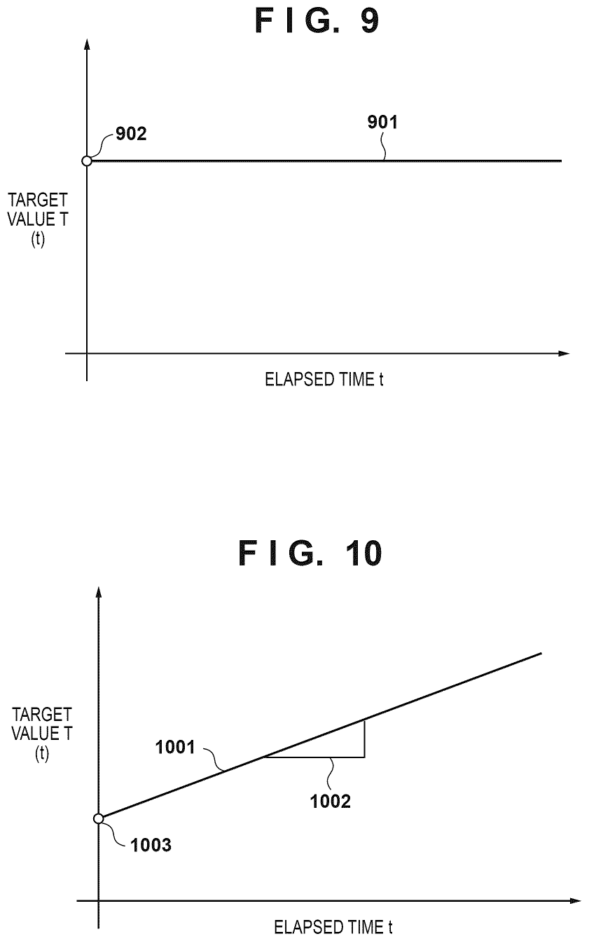

FIG. 9 shows a graph 901 (control profile) where the control parameter has a constant value 902 regardless of the time t. A function representing the graph 901 is expressed by

T(t)=c

where c is a constant.

For the graph 901, c is used as the approximation parameter for approximating the graph.

FIG. 10 shows a graph 1001 (control profile) where the control parameter changes proportionally to the time t. A function representing the graph 1001 is expressed by

T(t)=at+b

where a and b are constants. a indicates a slope 1002, and b indicates an intercept 1003.

For the graph 1001, a and b are used as approximation parameters for approximating the graph.

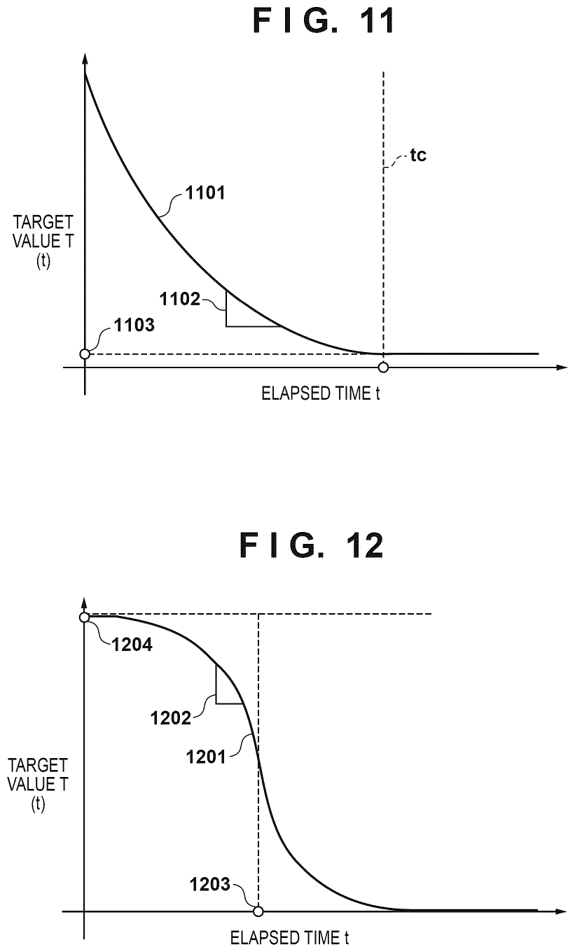

FIG. 11 shows a graph 1101 (control profile) where the control parameter changes nonlinearly with respect to the time t. A function representing the graph 1101 in a period where the time t ranges from 0 to tc is expressed by a polynomial

T(t)=aₙtⁿ+aₙ₋₁tⁿ⁻¹+ . . . +a₁t+a₀

where a coefficient aₖ in each term indicates a slope 1102 in the graph 1101.

A function representing the graph 1101 in a period from time tc is expressed by

T(t)=a₀

where a₀ indicates an intercept 1103.

For the graph 1101, aₖ and tc are used as approximation parameters for approximating the graph. In this manner, it is also possible to set a different equation for each section.

FIG. 12 shows a graph 1201 (control profile) where the control parameter changes according to an S-shaped curve with respect to the time t. A function representing the graph 1201 is expressed by

T(t)=a/{(1+(b−1)e^{-ct})}

where a indicates an intercept 1204, b indicates an inflection point 1203, and c indicates a slope 1202.

For the graph 1201, a, b, and c are used as approximation parameters for approximating the graph.

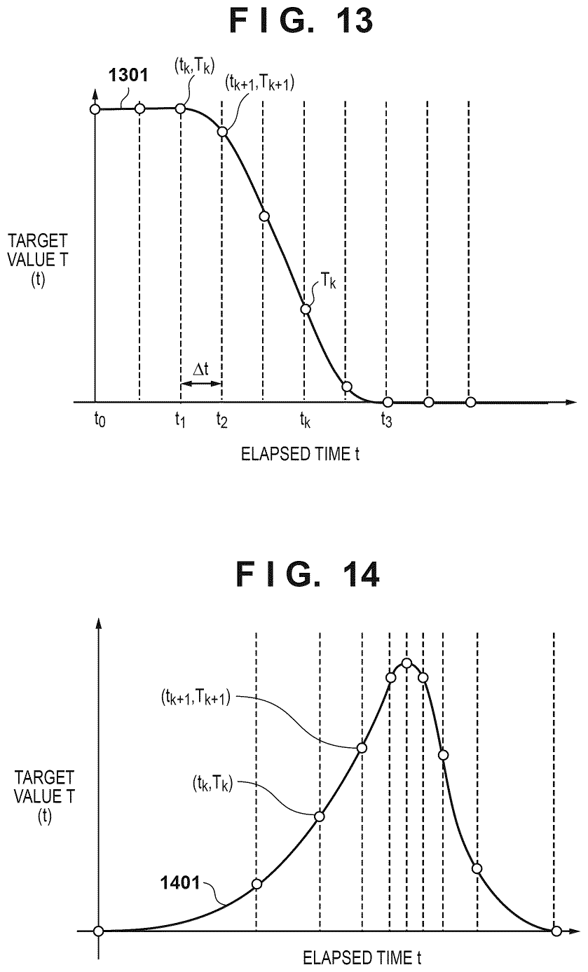

FIG. 13 shows a graph 1301 (control profile) where the control parameter is represented by a different curve for each section of the time t. A function representing the graph 1301 can be expressed using the value of the time t which changes for each period Δt, and a control parameter T at the time t, and expressed by

T(t)=T2+{(T2−T1)/(t2−t1)}(t−t1)

for (t1≤t≤t2)

Here, the control parameter value in the section between t1 and t2 can be calculated from two points of time t1 and time t2. Accordingly, the curve can be represented with fewer data.

As described above, in the method of approximating a curve by dividing it into time sections, a combination of the time t and the value T at the time t for each section, that is, (t0, T0), (t1, T1), . . . , (tn, Tn) are used as approximation parameters.

FIG. 14 shows a graph 1401 (control profile) where the control parameter is represented by a curve that changes for each section of the time t. In FIG. 14, the graph 1401 is spline-interpolated. Spline interpolation is a method of generating a smooth path by interpolating between discrete points using a cubic polynomial when discrete command points are given. In spline interpolation, for (n+1) discrete points including (t0, T0), . . . , (tn, Tn), a polynomial that interpolates between a discrete point (tk, Tk) and a discrete point (tk+1, Tk+1) can be expressed as

Tₖ(t)=aₖ(t−tₖ)³+bₖ(t−tₖ)²+cₖ(t−tₖ)+dₖ

where k=0 to n−1.

Here, a condition is given that the end point of the preceding section of adjacent sections is connected to the start point of the subsequent section, and the slope at the end point of the preceding section and the slope at the start point of the subsequent section are the same. In this manner, when spline interpolation is performed using (n+1) command points, (n+1) discrete points including (t0, T0), . . . , (tn, Tn) and coefficients (a₀, b₀, c₀, d₀), . . . , (aₙ₋₁, bₙ₋₁, cₙ₋₁, dₙ₋₁) of polynomials each of which interpolates each section are used as approximation parameters.

In this manner, in step S05, to approximate the control profile, approximation parameters that represent the control profile with a smaller finite number of parameters are extracted from the control parameters. As described above, in Example 1, the control profile can be represented by a linear function, a nonlinear function, an S-shape function, or a spline function.

In step S06, the processor 301 updates the approximation parameters (one or more parameter values) extracted in step S05. In Example 1, there can be a trade-off among the multiple indices to be evaluated, so there is basically no single optimal solution. Therefore, the dominance relationship among solutions is used to perform comparison and determine superior/inferior conditions. Evaluating multiple indices to find the optimal solution is called multi-objective optimization.

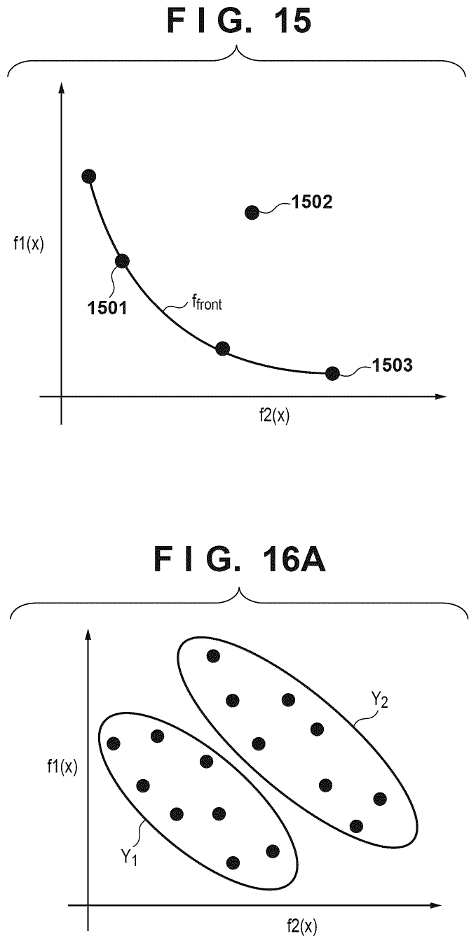

FIG. 15 is a graph showing the dominance relationship among solutions. FIG. 15 shows an example of minimizing two indices f₁(x) and f₂(x) by using an approximation parameter x. Points 1501, 1502, and 1503 are evaluation values respectively obtained under given conditions. At this time, the point 1502 is inferior to the point 1501 in terms of both f₁ and f₂, so that it can be said that the point 1501 dominates the point 1502. On the other hand, the points 1501 and 1503 are superior and inferior to each other at the same time, so that they are called incomparable. In general, a set of all solutions that are not dominated by other solutions and arbitrary solutions is called a Pareto set, and an image f_{front} of the Pareto set in the objective space shown in FIG. 15 is called the Pareto front. In multi-objective optimization, the approximation parameter x is updated with the aim of moving the f_{front} in the desired direction, that is, toward the origin of the graph in this example.

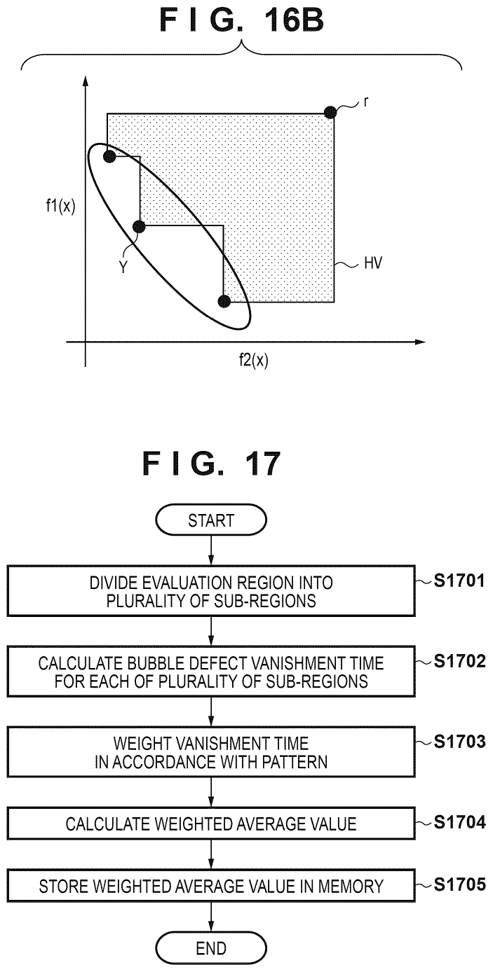

With reference to FIGS. 16A and 16B, Multiobjective Tree-Structured Parzen Estimator (MOTPE), which is one of multi-objective optimization methods, will be described. MOTPE is a type of multi-objective Bayesian optimization. In MOTPE, as shown in FIG. 16A, solutions within a search space are divided into a promising point group Y₁ and an unpromising point group Y_{g}, and a model is constructed for each group by using kernel density estimation. With this, the probability densities of the superior solution group and the inferior solution group in the search space are individually estimated. After the models are constructed, the next solution to evaluate is determined based on an acquisition function EHVI (Expected Hypervolume Improvement).

FIG. 16B is a view for explaining Hypervolume. A set Y is the Pareto set described above, and a point r is an arbitrary coordinate point where all indices are inferior, which is called a reference point, that is, where both f₁ and f₂ are large in this example. At this time, a hypervolume HV is defined as the volume of a region surrounded by the set Y and the reference point r as shown in FIG. 16B. It can be seen that the hypervolume HV defined in this manner increases when the Pareto front is moved forward. The acquisition function EHVI is defined so as to correspond to the expected increase value of the hypervolume HV. Accordingly, by selecting x that maximizes this when a new point y=f(x) is added to the existing set Y, a solution that can increase the hypervolume most by the expected value is obtained. Furthermore, letting l(x) and g(x) be the estimated probability densities of the promising point group Y₁ and the unpromising point group Y_{g}, respectively, it is known that maximizing a density ratio l(x)/g(x) maximizes the acquisition function EHVI. Hence, MOTPE repeatedly calculates the density ratio l(x)/g(x), and determines, as the updated x, the value of x that maximizes the density ratio. Thus, the optimal parameter can be calculated.

As another example of the multi-objective optimization method, an optimization algorithm such as a Nelder-Mead method or evolutionary multi-objective optimization can also be used.

In a case where the number of approximation parameters is small, it is also possible to calculate evaluation values for all combinations of approximation parameters, and use the combination of approximation parameters that yields the optimal evaluation value.

Note that, when the approximation parameter is updated, it is determined whether an imprint operation can be performed using the updated parameter, thereby confirming that no inappropriate approximation parameter is used.

In step S07, the processor 301 determines the control profile based on the adjusted one or more parameter values. More specifically, the control profile is determined by applying, to the control profile, the one or more parameter values adjusted through steps S02 to S06. The control profile determined in step S07 is output from the processor 301 and, for example, can be stored in the memory 302 as a text file describing the control profile. The imprint apparatus IMP performs the imprint process (shaping process) by controlling each operation mechanism using the control profile determined through the flowchart of FIG. 4. With this, occurrence of shaping failure such as non-filling defects (bubble defects) can be reduced.

As described above, according to the control parameter optimization method in Example 1, it is possible to automatically calculate an optimal control parameter using the calculation results of the simulator. In addition, by dividing the cell region and minimizing the variation in the evaluation values of the sub-regions, an optimal control parameter can be calculated, which prevents uneven distribution of bubble defects in the region where filling performance is locally poor. Therefore, even if the mold includes a corner portion prone to bubble defects or a complex pattern where resist filling is difficult, an optimal control parameter can be provided in a short time without human intervention.

Example 1 has been described for the imprint operation for forming the pattern by bringing the mold into contact with the imprint material, but it can also be used to calculate a control parameter in the mold separation operation of separating the mold M from the imprint material on the substrate S.

A planarization apparatus can planarize a substrate by bringing a flat mold having no pattern into contact with the substrate. This method can also be used to calculate a control parameter related to a contact operation or a mold separation operation in the planarization apparatus.

### Example 2

In Example 2, a method of calculating control parameters that selectively change the bubble defect vanishment time for each sub-region in accordance with the importance of the pattern of the mold or the like will be described.

The general procedure of the determination method described in Example 2 is similar to that in Example 1, and follows the procedure illustrated in FIG. 4. In Example 2, the evaluation value calculation method performed in step S03 is different from that in Example 1.

The procedure of the evaluation value calculation method in Example 2 is illustrated in FIG. 17. In step S1701, the processor 301 divides the imprint evaluation region into a plurality of sub-regions. This is similar to step S601 of FIG. 6. Step S1702 is a step (first step) of obtaining, for each of the plurality of sub-regions obtained by dividing the region where the shaping process is performed, a sub-evaluation value concerning the state of the composition in a case where the shaping process is performed under the acquired processing condition. For example, in step S1702, the processor 301 obtains the bubble defect vanishment time for each of the plurality of sub-regions obtained in step S1701. This is similar to step S602 of FIG. 6.

Steps S1703 and S1704 constitute a step (second step) of obtaining an evaluation value based on a plurality of sub-evaluation values obtained for the plurality of sub-regions. For example, in step S1703, the processor 301 multiplies each obtained vanishment time (sub-evaluation value) by a weighting coefficient. The weighting coefficient is determined in accordance with the characteristics of the pattern included in each sub-region. For example, if the sub-region includes a mark pattern for alignment, bubble defects need to vanish around the mark pattern in an earlier stage than in other regions to make it easier for the resist to fill into the mark pattern before alignment starts. In this case, the area around the mark pattern is designated as a division region, and the weighting coefficient for the division region is increased.

In step S1704, the processor 301 obtains the average (weighted average value) of the weighted evaluation values. If the bubble defect vanishment time is slow in the region with a large weighting coefficient, the average value serving as the final evaluation value is likely to deteriorate. Therefore, an optimal control parameter is obtained from a condition where bubble defects are filled more rapidly in a region with a larger weighting coefficient and more slowly in a region with a smaller weighting coefficient.

In step S1705, the processor 301 stores the weighted average value of the evaluation values obtained in step S1704 in the memory 302.

In this manner, in Example 2, the weighted average value of the plurality of sub-evaluation values is obtained as the evaluation value. By applying weighting to each sub-region as described above, it is possible to obtain an optimal control parameter that considers the pattern arrangement more flexibly than in Example 1.

### <Embodiment of Article Manufacturing Method>

The pattern of a cured product formed using an imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are a mold for imprint and the like.

The pattern of the cured product is directly used as the constituent member of at least some of the above-described articles or used temporarily as a resist mask. After etching or ion implantation is performed in the substrate processing step, the resist mask is removed.

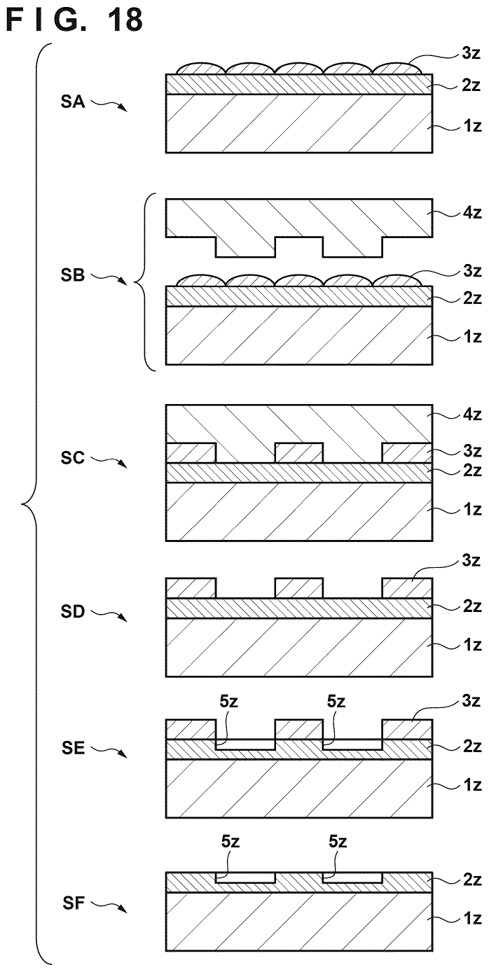

Next, an article manufacturing method will be described with reference to FIG. 18. In step SA, a substrate 1z such as a silicon substrate with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

In step SB, a side of a mold 4z for imprint with a concave-convex pattern is directed to face the imprint material 3z on the substrate. In step SC, the mold 4z and the substrate 1z to which the imprint material 3z has been applied are brought into contact with each other, and a pressure is applied. The gap between the mold 4z and the processed material 2z is filled with the imprint material 3z. In this state, when the imprint material 3z is irradiated with light as curing energy via the mold 4z, the imprint material 3z is cured.

In step SD, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave-convex pattern of the mold 4z is transferred to the imprint material 3z.

In step SE, when etching is performed using the pattern of the cured product as an etching resistant mask, a portion of the surface of the processed material 2z where the cured product does not exist or remains thin is removed to form a groove 5z. In step SF, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

According to the embodiment described above, a technique advantageous for suppressing shaping failure can be provided.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-037707, filed Mar. 10, 2025 which is hereby incorporated by reference herein in its entirety.

What is claimed is:

1. A determination method of determining a control profile used to control a mechanism operated in a shaping process of shaping a composition on a substrate using a mold, the method comprising:
acquiring a processing condition used for the shaping process;
obtaining an evaluation value concerning a state of the composition in a case where the shaping process is performed under the processing condition;
adjusting an element constituting a function representing the control profile so that the evaluation value falls within a predetermined range; and
determining the control profile based on the adjusted element,
wherein the obtaining the evaluation value includes
obtaining, for each of a plurality of sub-regions obtained by dividing a region where the shaping process is performed, a sub-evaluation value concerning a state of the composition in a case where the shaping process is performed under the processing condition, and
obtaining the evaluation value based on a plurality of sub-evaluation values obtained for the plurality of sub-regions.

2. The method according to claim 1, wherein
in the obtaining the evaluation value based on the plurality of sub-evaluation values, an index indicating a variation in the plurality of sub-evaluation values is obtained as the evaluation value.

3. The method according to claim 2, wherein
the index is a standard deviation of the plurality of sub-evaluation values.

4. The method according to claim 2, wherein
the index is a variance of the plurality of sub-evaluation values.

5. The method according to claim 2, wherein
the index is a coefficient of variation of the plurality of sub-evaluation values.

6. The method according to claim 1, wherein
in the obtaining the evaluation value based on the plurality of sub-evaluation values, a first index indicating a variation of the plurality of sub-evaluation values, and a second index indicating one of a minimum value and an average value of the plurality of sub-evaluation values are obtained as the evaluation value.

7. The method according to claim 1, wherein
in the obtaining the evaluation value based on the plurality of sub-evaluation values, a weighted average value of the plurality of sub-evaluation values is obtained as the evaluation value.

8. The method according to claim 1, wherein
the obtaining the evaluation value is performed using a simulation of predicting a behavior of the composition in the shaping process.

9. The method according to claim 1, wherein
the obtaining the evaluation value is performed using a result of the shaping process performed on a test substrate.

10. The method according to claim 1, wherein
in the obtaining the evaluation value, a sub-evaluation value is obtained for each of the plurality of sub-regions based on at least one of a defect of the composition, a shape of the composition, and a position deviation of a pattern of the composition, which are generated by the shaping process.

11. The method according to claim 1, wherein
the element includes at least one of a coefficient and a constant that define the function.

12. The method according to claim 1, wherein
the control profile is a profile indicating a temporal driving target value of the mechanism in the shaping process.

13. The method according to claim 1, wherein
the control profile is represented by one of a linear function, a nonlinear function, an S-shaped function, and a spline function.

14. The method according to claim 1, wherein
the processing condition includes at least one of a density of a pattern provided in the mold, a depth of a concave portion of the pattern, a thickness of the composition shaped by the shaping process, and an arrangement of the composition supplied as a plurality of droplets onto the substrate.

15. The method according to claim 1, wherein
the shaping process is an imprint process of forming a pattern in the composition on the substrate using the mold having a pattern.

16. The method according to claim 1, wherein
the shaping process is a planarization process of planarizing the composition on the substrate using the mold having a flat surface.

17. A shaping method comprising:
determining, using a determination method defined in claim 1, a control profile used to control a mechanism configured to be operated in a shaping process of shaping a composition on a substrate using a mold; and
performing the shaping process by controlling the mechanism based on the determined control profile.

18. An article manufacturing method comprising:
shaping a composition on a substrate using a shaping method defined in claim 17;
processing the substrate including the shaped composition, and
manufacturing an article from the processed substrate.

19. An information processing apparatus that determines a control profile used to control a mechanism configured to be operated in a shaping process of shaping a composition on a substrate using a mold, the apparatus comprising:
an acquisition unit configured to acquire a processing condition used for the shaping process;
an evaluation unit configured to obtain an evaluation value concerning a state of the composition in a case where the shaping process is performed under the processing condition;
an adjustment unit configured to adjust an element constituting a function representing the control profile so that the evaluation value falls within a predetermined range; and
a determination unit configured to determine the control profile based on the adjusted element,
wherein the evaluation unit is configured to
obtain, for each of a plurality of sub-regions obtained by dividing a region where the shaping process is performed, a sub-evaluation value concerning a state of the composition in a case where the shaping process is performed under the processing condition, and
obtain the evaluation value based on a plurality of sub-evaluation values obtained for the plurality of sub-regions.

20. A computer-readable storage medium storing a program for causing a computer to execute a process of determining a control profile used to control a mechanism configured to be operated in a shaping process of shaping a composition on a substrate using a mold, wherein
the program causes the computer to function as
an acquisition unit configured to acquire a processing condition used for the shaping process,
an evaluation unit configured to obtain an evaluation value concerning a state of the composition in a case where the shaping process is performed under the processing condition,
an adjustment unit configured to adjust an element constituting a function representing the control profile so that the evaluation value falls within a predetermined range, and
a determination unit configured to determine the control profile based on the adjusted element, and
the evaluation unit is configured to
obtain, for each of a plurality of sub-regions obtained by dividing a region where the shaping process is performed, a sub-evaluation value concerning a state of the composition in a case where the shaping process is performed under the processing condition, and
obtain the evaluation value based on a plurality of sub-evaluation values obtained for the plurality of sub-regions.

21. A shaping apparatus that performs a shaping process of shaping a composition on a substrate using a mold, comprising:
a mechanism configured to be operated in the shaping process; and
a control unit configured to acquire a control profile determined using an information processing apparatus defined in claim 19, and control the mechanism based on the control profile.
